(19) United States
(12) Patent Application Publication
(10) Pub. No.: US 2019/0304524 A1
(43) Pub. Date: Oct. 3, 2019

(54) SPIN ORBIT TORQUE (SOT) MEMORY DEVICES WITH ENHANCED STABILITY AND THEIR METHODS OF FABRICATION

(71) Applicants: Kaan Oguz, Portland, OR (US); Charles Kuo, Hillsboro, OR (US); Mark Doczy, Beaverton, OR (US); Kevin O'Brien, Portland, OR (US)

(72) Inventors: Kaan Oguz, Portland, OR (US); Charles Kuo, Hillsboro, OR (US); Mark Doczy, Beaverton, OR (US); Kevin O'Brien, Portland, OR (US)

(21) Appl. No.: 15/942,349

(22) Filed: Mar. 30, 2018

(51) Int. Cl. G11C 11/16; H01L 43/12; H01L 43/10; H01L 27/22

(52) U.S. Cl. CPC G11C 11/161; H01L 43/12; H01L 27/22; G11C 11/1673; H01L 43/10

(57) ABSTRACT

A perpendicular spin orbit torque (SOT) memory device includes an electrode having a spin orbit torque material and a perpendicular magnetic tunnel junction (pMTJ) device on a portion of the electrode. The pMTJ device includes a free magnet structure electrode, where the free magnet structure includes a free magnet that is dipole coupled with a magnetic stability enhancement layer. The pMTJ device further includes a fixed layer and a tunnel barrier between the free layer and the fixed layer.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, lending to the fabrication of products with increased functionality. The drive for ever-more functionality, however, is not without issue. It has become increasingly significant to rely on innovative devices such as spin orbit torque (SOT) memory devices including a spin orbit torque electrode coupled with a compatible MTJ device to overcome the requirements imposed by scaling.

Non-volatile embedded memory with SOT memory devices, e.g., on-chip embedded memory with non-volatility can enable energy and computational efficiency. However, the technical challenges of assembling a material layer stack to form functional SOT memory devices present formidable roadblocks to commercialization of this technology today. Specifically, increasing thermal stability in SOT memory devices are some important areas of device development.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1A illustrates a cross-sectional view of a spin orbit torque (SOT) memory device, in accordance with an embodiment of the present disclosure.

FIG. 1B illustrates a plan view of a magnetic tunnel junction (MTJ) device disposed on a spin orbit torque electrode, in accordance with an embodiment of the present disclosure.

FIG. 1C illustrates a cross-sectional view of alternating stack of layers of magnetic and non-magnetic materials in a ferromagnet.

FIG. 1D illustrates a cross-sectional view of alternating stack of layers of non-magnetic and magnetic materials capped by a magnetic material in a ferromagnet.

FIG. 1E illustrates a cross-sectional view of alternating stack of layers of non-magnetic and magnetic materials in a ferromagnet.

FIG. 1F illustrates a cross-sectional view depicting the direction of magnetization in a free magnet relative to the direction of magnetization in a fixed magnetic layer, in accordance with an embodiment of the present disclosure.

FIG. 1G illustrates a cross-sectional view depicting the direction of magnetization in a free magnet relative to the direction of magnetization in a fixed magnetic layer, in accordance with an embodiment of the present disclosure.

FIGS. 1H illustrates a cross-sectional view of individual layers of a synthetic antiferromagnetic structure, in accordance with an embodiment of the present disclosure.

FIG. 2 illustrates a cross-sectional view of a SOT memory device, in accordance with an embodiment of the present disclosure.

FIG. 3A illustrates a SOT memory device in a low resistance state.

FIG. 3B illustrates a SOT memory device switched to a high resistance state after the application of a spin hall current and an external magnetic field.

FIG. 3C illustrates a SOT memory device switched to a low resistance state after the application of a spin hall current and an external magnetic field.

FIG. 4A illustrates a cross-sectional view of the formation of an electrode layer including a spin orbit torque (SOT) material on a dielectric layer formed above a substrate, in an accordance with embodiments of the present disclosure.

FIG. 4B illustrates a cross-sectional view of the structure in FIG. 4A following the formation of a mask to pattern the electrode layer.

FIG. 4C illustrates a cross-sectional view of the structure in FIG. 4B following patterning of the electrode layer to form an electrode including then SOT material.

FIG. 4D illustrates a cross-sectional view of the structure in FIG. 4C following the deposition of a dielectric layer on the electrode and planarization of the dielectric layer and the mask.

FIG. 4E illustrates a plan view of the structure in FIG. 4D depicting a shape of the electrode including the SOT material.

FIG. 4F illustrates a cross-sectional view of the structure in FIG. 4D following the formation of a free magnet structure including a magnetic stability enhancement layer on the electrode and on the dielectric layer, a spacer on the magnetic stability enhancement layer, and a free magnet on the spacer.

FIG. 4G illustrates a cross-sectional view of the structure in FIG. 4E following the formation of a tunnel barrier layer, a fixed magnetic layer, a SAF structure, and a capping electrode layer to form a material layer stack for magnetic tunnel junction device.

FIG. 4H illustrates a cross-sectional view of the structure in FIG. 4G following the process of etching the material layer stack to form a magnetic tunnel junction device on the electrode including the SOT material.

FIG. 4I illustrates a cross-sectional view of the structure in FIG. 4H following the formation of a dielectric spacer adjacent to the magnetic tunnel junction device and on portions of the electrode.

FIG. 5 illustrates a cross-sectional view of a SOT memory device coupled having one terminal coupled to a first transistor, a second terminal coupled to a second transistor, and a third terminal coupled to a bit line.

FIG. 6 illustrates a computing device in accordance with embodiments of the present disclosure.

FIG. 7 illustrates an integrated circuit (IC) structure that includes one or more embodiments of the present disclosure.

### DESCRIPTION OF THE EMBODIMENTS

Spin orbit torque (SOT) memory devices with enhanced stability and their methods of fabrication are described. In the following description, numerous specific details are set forth, such as novel structural schemes and detailed fabrication methods in order to provide a thorough understanding of embodiments of the present disclosure. It will be apparent to one skilled in the art that embodiments of the present disclosure may be practiced without these specific details. In other instances, well-known features, such as transistor operations and switching operations associated with embedded memory, are described in lesser detail in order to not unnecessarily obscure embodiments of the present disclosure. Furthermore, it is to be understood that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In the following description, numerous details are set forth. However, it will be apparent to one skilled in the art, that the present disclosure may be practiced without these specific details. In some instances, well-known methods and devices are shown in block diagram form, rather than in detail, to avoid obscuring the present disclosure. Reference throughout this specification to “an embodiment” or “one embodiment” or “some embodiments” means that a particular feature, structure, function, or characteristic described in connection with the embodiment is included in at least one embodiment of the disclosure. Thus, the appearances of the phrase “in an embodiment” or “in one embodiment” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example, in the context of materials, one material or material disposed over or under another may be directly in contact or may have one or more intervening materials. Moreover, one material disposed between two materials may be directly in contact with the two layers or may have one or more intervening layers. In contrast, a first material “on” a second material is in direct contact with that second material/material. Similar distinctions are to be made in the context of component assemblies.

As used throughout this description, and in the claims, a list of items joined by the term “at least one of' or “one or more of' can mean any combination of the listed terms. For example, the phrase

A SOT memory device may include a magnetic tunnel junction (MTJ) device formed on a spin orbit torque electrode. The MTJ device functions as a memory device where the resistance of the MTJ device switches between a high resistance state and a low resistance state. The resistance state of an MTJ device is defined by the relative orientation of magnetization between a free magnet and a fixed magnet that are separated by a tunnel barrier. When the magnetization of the free magnet and a fixed magnet have orientations that are in the same direction, the MTJ device is said to be in a low resistance state. Conversely, when the magnetization of the free magnet and a fixed magnet each have orientations that are in opposite direction to each other, the MTJ device is said to be in a high resistance state.

In an embodiment, in an absence of a spin orbit torque electrode, resistance switching in an MTJ device is brought about by passing a critical amount of spin polarized current through the MTJ device so as to influence the orientation of the magnetization of the free magnet to align with the magnetization of the fixed magnet. The act of influencing the magnetization is brought about by a phenomenon known as spin torque transfer, where the torque from the spin polarized current is imparted to the magnetization of the free magnet. By changing the direction of the current, the direction of magnetization in the free magnet may be reversed relative to the direction of magnetization in the fixed magnet. Since the free magnet does not need a constant source of spin polarized current to maintain a magnetization direction, the resistance state of the MTJ device is retained even when there is no current flowing through the MTJ device. For this reason, the MTJ device belongs to a class of memory known as non-volatile memory.

As an MTJ device is scaled down in size, the amount of critical spin polarized current density required to switch the device increases. By implementing an MTJ device on a SOT electrode, the magnetization in the free magnet may undergo torque assisted switching from a Spin Hall current, induced by passing an electrical current through the SOT electrode in a direction transverse to a thickness of the MTJ device material stack. The Spin Hall current arises from spin dependent scattering of electrons due to a phenomenon known as spin orbit interaction. Electrons of one spin polarity are directed towards an upper portion of the spin orbit torque electrode and electrons with an opposite spin polarity are directed toward a bottom portion of the spin orbit torque electrode. Electrons of a particular spin polarity are directed toward the MTJ device and impart a spin orbit torque on the magnetization of the free magnet. The spin hall current may also help the MTJ device switch faster. It is to be appreciated that, in an embodiment, the spin hall current can fully switch a free magnet having a magnetization that is oriented in an in-plane direction. An in-plane direction is defined as a direction that is parallel to an uppermost surface of the spin orbit torque electrode. An external field may be utilized to exert a torque to completely switch the perpendicular free magnet from an in plane direction.

Integrating a non-volatile memory device such as an SOT memory device onto access transistors enables the formation of embedded memory for system on chip (SOC) applications. However, approaches to integrate an SOT memory device onto access transistors presents challenges that have become far more formidable with scaling. One such challenge is the need to improve stability of the SOT memory device against thermal fluctuations during the lifetime of a device. Thermal fluctuations can cause unwanted reversal of magnetization of the free magnet, the fixed magnet or both, leading to loss of information stored in an SOT memory device. As the MTJ memory device in the SOT memory device typically includes a multilayer stack of magnetic and non-magnetic materials, the stack is engineered for thermal stability. The thermal stability of the multilayer stack depends on the strength of the magnetic anisotropy and on the thickness of the free magnet in the MTJ memory device.

In some embodiments, the free magnet further includes two magnetic layers separated by a coupling layer to increase thermal stability. A first magnetic layer is adjacent to the tunnel barrier and a second magnetic layer is in contact with the spin orbit torque electrode. The thermal stability of the free magnet may be increased due to an increase in magnetism called interfacial magnetic anisotropy arising from interfaces between each of the first and second magnetic layers and the adjacent non-magnetic coupling layer. While thermal stability may be increased, switching current may be impacted when there are multiple magnets that are required to undergo magnetization switching. Switching current may be minimized, however, when the magnetic layer that is proximal to (e.g., in physical contact with) the spin orbit torque electrode is able to favorably utilize the polarized Spin Hall current to initiate the magnetization switching and influence the second of the magnetic layers proximal to the tunnel barrier to switch magnetization orientation. Such a phenomenon may be realized when the magnetic layer that is proximal to the spin orbit torque electrode has a magnetic anisotropy that is greater than the magnetic anisotropy of the magnetic layer proximal to the tunnel barrier.

When the two magnetic layers of a free magnet are ferromagnetically coupled, thermal stability may also be increased. Ferromagnetic coupling takes place through a phenomenon known as magnetic dipole coupling through a second coupling layer between the first and the second magnetic layers in a free magnet, and may be enhanced by tuning the second coupling layer composition and thickness. Depending on embodiments, the second coupling layer may include a highly conductive material such as a metal, or a partially conductive material such as a dielectric layer that permits electron tunneling.

As MTJ devices (formed on spin orbit torque electrode) are scaled, the need for smaller memory cell size has driven the industry in the direction of perpendicular MTJs. Perpendicular MTJs are memory devices where the fixed magnet and the free magnet have magnetic anisotropy that is perpendicular with respect to a plane defining an uppermost surface of the spin orbit torque electrode. Relative to an in-plane device, a perpendicular MTJ with a ferromagnetically coupled free magnet having at least two magnetic layers on a spin orbit torque electrode has several advantages, such as increased thermal stability.

In accordance with embodiments of the present disclosure, a spin orbit torque (SOT) memory device includes a first electrode including a spin orbit torque material and a magnetic tunnel junction (MTJ) device coupled with the first electrode. In an embodiment, the first electrode has uppermost surface area that is 10 to 20 times larger than a lowermost surface area of the MTJ device. In an embodiment, the MTJ device includes a free magnet structure that includes a magnetic enhancement layer to improve stability (herein referred to as a magnetic stability enhancement layer), a free magnet, and a spacer between magnetic stability enhancement layer and the free magnet. The magnetic stability enhancement layer may be a magnetic material. The free magnet is coupled with the magnetic stability enhancement layer. The spacer enables ferromagnetic coupling between the magnetic stability enhancement layer and the free magnet. The free magnet structure collectively undergoes magnetization switching. In an exemplary embodiment, the magnetic stability enhancement layer undergoes magnetization switching first and then the free magnet switches in response to magnetization switching of the magnetic stability enhancement layer. The MTJ device further includes a fixed magnet having a magnetization that does not change orientation during operation of the SOT memory device, a tunnel barrier between the free magnet and the fixed magnet, and a second electrode coupled with the fixed magnet.

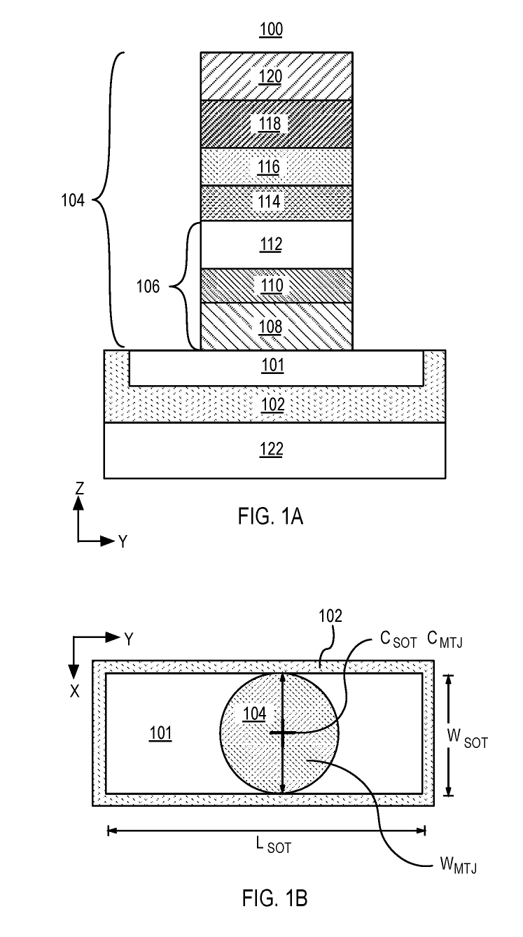

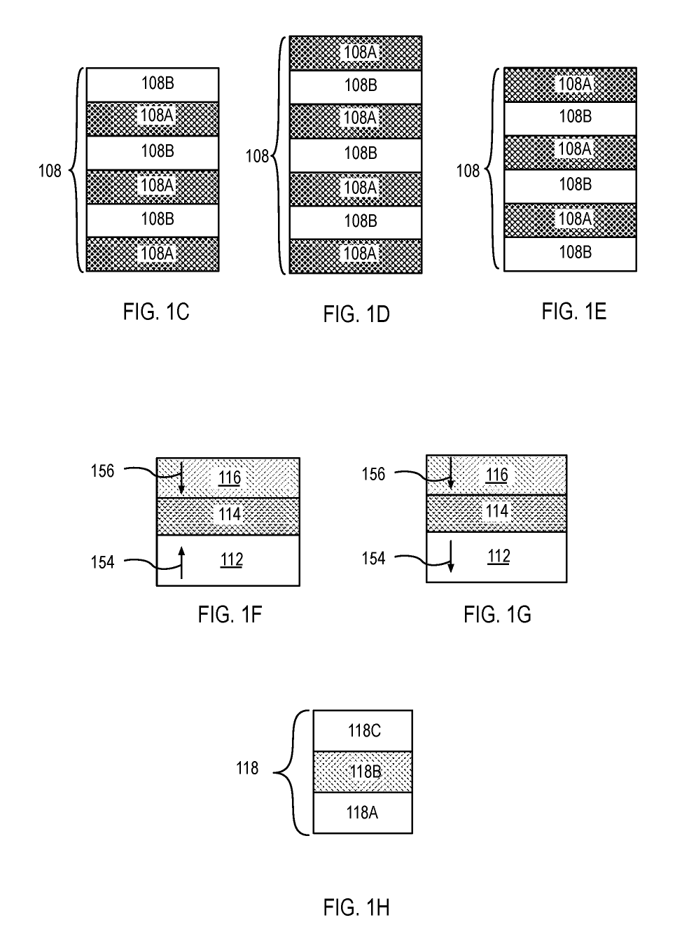

FIG. 1A is an illustration of a cross-sectional view of a SOT memory device 100 in accordance with an embodiment of the present disclosure. The SOT memory device 100 includes an electrode 101 having a spin orbit torque material, and a material layer stack for a magnetic tunnel junction (MTJ) device 104 on the electrode 101. In some embodiments, such as in the illustrative embodiment, the magnetic tunnel junction (MTJ) device 104 is a perpendicular MTJ (pMTJ) device 104. An SOT memory device 100 that includes a pMTJ device 104, is herein referred to as a perpendicular SOT (pSOT) memory device 100. In an embodiment, the pMTJ device 104 is approximately in the center of the electrode 101, as shown in the plan view illustration of FIG. 1B.

Referring again to FIG. 1A, the material layer stack for a pMTJ device 104 includes a free magnet structure 106. The free magnet structure 106 includes a magnetic stability enhancement layer 108 on the electrode 101, a spacer 110 on the magnetic stability enhancement layer 108, and a free magnet 112 on the spacer 110. In the illustrative embodiment, the magnetic stability enhancement layer 108 has a magnetic anisotropy that is greater than a magnetic anisotropy of the free magnet 112. The magnetic stability enhancement layer 108 advantageously improves thermal stability of the MTJ device 104. The spacer 110 couples the magnetic stability enhancement layer 108 to free magnet 112 via dipole coupling. The dipole coupling is proportional to the saturation magnetization and thickness of the magnetic stability enhancement layer 108 and free magnet 112. The pMTJ device 104 further includes a tunnel barrier 114 on the free magnet 112, and a fixed magnet 116 on the tunnel barrier 114.

The electrode 101 includes a metal with high degree of spin orbit coupling. A metal with a high degree of spin-orbit coupling has an ability to inject a large spin polarized current in to the free magnet structure 106. A large spin polarized current can exert a large amount of torque and influence the magnetization of the free magnet structure 106 for faster switching. In an embodiment, the electrode 101 includes a metal such as but not limited to tantalum, tungsten, platinum or gadolinium. In an embodiment, electrode 101 includes a beta phase tantalum or beta phase tungsten. An electrode 101 including a beta phase tantalum or beta phase tungsten has a high spin hall efficiency. With a high spin hall efficiency, the electrode 101 can generate a large spin hall current for a given charge current that is passed through the electrode 101. In an embodiment, the electrode 101 has thickness of between 2 nm and 20 nm.

In an embodiment, the magnetic stability enhancement layer 108 includes an alloy of a magnetic material and a non-magnetic material. In some embodiments, the non-magnetic material includes a metal such as platinum, palladium and iridium, and the magnetic material includes a metal such as cobalt or iron. In another embodiment, the magnetic stability enhancement layer 108 is a ferrimagnet alloy including manganese and at least one other element, such as germanium, aluminum or gallium. The magnetic stability enhancement layer 108 may have a thickness between 4 nm and 10 nm for perpendicular MTJ devices.

In some embodiments, the magnetic stability enhancement layer 108 includes a multilayer stack of alternating layers of magnetic layer 108A and a non-magnetic layer 108B on the magnetic layer 108A, as is illustrated in FIG. 1C. To maintain a greater degree of anisotropy compared to the anisotropy of the free magnet 112, the alternating layers of the multilayer stack ranges from at least 2 to 10 layers of each magnetic layer 108A and non magnetic layer 108B. A stack depicting 3 layers of each magnetic layer 108A and non magnetic layer 108B is depicted in FIG. 1C. The non-magnetic layer 108B may include a metal such as platinum, palladium or iridium, and magnetic layer 108A may include a magnetic material such as cobalt. Examples of thicknesses of the non-magnetic layer 108B ranges from 0.2 nm and 1 nm and the magnetic layer 108A ranges from 0.2 nm and 1.0 nm. The total combined thickness of the multilayer stack may range between 4 nm and 10 nm. When the magnetic stability enhancement layer 108 includes a multilayer stack such as is depicted in FIG. 1C, the magnetic layer 108A is directly adjacent to the spin orbit torque material of electrode 101, and a non-magnetic layer 108B is adjacent to the spacer 110.

FIG. 1D illustrates cross sectional view of the multilayer stack depicted in FIG. 1C that is capped by a magnetic layer 108A. In such an illustrative embodiment, a magnetic layer 108A is directly adjacent to the spin orbit torque material of electrode 101, and a second magnetic layer 108A is adjacent to the spacer 110 (FIG. 1A).

In other embodiments, the magnetic stability enhancement layer 108 includes a multilayer stack of alternating layers of non-magnetic layer 108B and a magnetic layer 108A on the non-magnetic layer 108B, as illustrated in FIG. 1E. In this illustrative embodiment, a non-magnetic layer 108B is directly adjacent to the spin orbit torque material of electrode 101, and a magnetic layer 108A is adjacent to the spacer 110.

Referring again to FIG. 1A, in an embodiment, the spacer 110 includes a non-magnetic metal such as copper, platinum, palladium, and titanium. In other embodiments, the spacer 110 includes oxygen and at least one other element such as magnesium, tungsten, tantalum, titanium, copper or silicon. Such a layer may have a higher resistivity than when the spacer 110 is a non-magnetic metal. An increased electrical resistivity may not impede functionality of the pSOT memory device 100. An amount of read current, ranging between 1 microamps to 100 microamps may be transmitted through the pMTJ device 104 and may enable reading a magnetic state of the free magnet structure 106. Depending on the material utilized, the coupling layer may have a thickness between 3 nm and 5 nm. When the spacer 110 has a thickness between 3 nm and 5 nm, the magnetic stability enhancement layer 108 and the free magnet 112 can be ferromagnetically coupled by the stray fields produced by the magnetic stability enhancement layer 108 and the free magnet 112.

In an embodiment, the free magnet 112 includes a magnetic material such as Co, Ni, Fe or alloys of these materials. In an embodiment, the free magnet 112 includes a magnetic material such as CoB, FeB, CoFe or CoFeB. In some embodiments, the free magnet 112 includes a Co_{100-x-y}FeₓB_{y}, where X and Y each represent atomic percent, further where X is between 50 and 80 and Y is between 10 and 40, and further where the sum of X and Y is less than 100. In one specific embodiment, X is 60 and Y is 20. In an embodiment, the free magnet 112 is FeB, where the concentration of boron is between 10 and 40 atomic percent of the total composition of the FeB alloy. In an embodiment, the free magnet 112 has a thickness between 0.9 nm and 2.0 nm for pMTJ devices.

In an embodiment, tunnel barrier 114 is composed of a material suitable for allowing electron current having a majority spin to pass through tunnel barrier 114, while impeding, at least to some extent, electron current having a minority spin from passing through tunnel barrier 114. Thus, tunnel barrier 114 (or spin filter layer) may also be referred to as a tunneling layer for electron current of a particular spin orientation. In an embodiment, tunnel barrier 114 includes a material such as, but not limited to, oxygen and at least one of magnesium (e.g., a magnesium oxide, or MgO), or aluminum (e.g., an aluminum oxide such as Al₂O₃). In an embodiment, tunnel barrier 114 including MgO has a crystal orientation that is (001) and is lattice matched to free magnet 112 below tunnel barrier 114 and fixed magnet 116 above tunnel barrier 114. In an embodiment, tunnel barrier 114 is MgO and has a thickness in the range of 1 nm to 2 nm. In an embodiment, a free magnet 112 including a Co_{100-x-y}FeₓB_{y}, is highly lattice matched to the tunnel barrier 114 including an MgO. Lattice matching a crystal structure of the free magnet 112 with the tunnel barrier 114 enables a higher tunneling magnetoresistance (TMR) ratio in the pMTJ device 104.

In some embodiments, the fixed magnet 116 includes a material and has a thickness sufficient for maintaining a fixed magnetization. In an embodiment, the fixed magnet 116 of the pMTJ device 104 includes an alloy such as CoFe or CoFeB. In an embodiment, the fixed magnet 116 comprises a Co_{100-x-y}FeₓB_{y}, where X and Y each represent atomic percent, further where X is between 50-80 and Y is between 10 and 40, and further where the sum of X and Y is less than 100. In one specific embodiment, X is 60 and Y is 20. In an embodiment, the fixed magnet 116 is FeB, where the concentration of boron is between 10 and 40 atomic percent of the total composition of the FeB alloy. In an embodiment the fixed magnet 116 has a thickness that is between 1 nm-3 nm.

FIG. 1F illustrates a cross-sectional view depicting the free magnet structure 106 of the pMTJ device 104 having a direction of magnetization (denoted by the direction of the arrow 154) that is anti-parallel to a direction of magnetization (denoted by the direction of the arrow 156) in the fixed magnet 116. When the direction of magnetization 154 in the free magnet structure 106 is opposite (anti-parallel) to the direction of magnetization 156 in the fixed magnet 116, the pMTJ device 104 device is said to be in a high resistance state.

Conversely, FIG. 1G illustrates a cross-sectional view depicting the free magnet structure 106 of the pMTJ device 104 having a direction of magnetization (denoted by the direction of the arrow 154) that is parallel to a direction of magnetization (denoted by the direction of the arrow 156) in the fixed magnet 116. When the direction of magnetization 154 in the free magnet structure 106 is parallel to the direction of magnetization 156 in the fixed magnet 116, the pMTJ device 104 is said to be in a low resistance state.

In an embodiment, the free magnet structure 106 and the fixed magnet 116 can have approximately similar thicknesses and an injected spin polarized current which changes the direction of the magnetization 154 in the free magnet structure 106 can also affect the magnetization 156 of the fixed magnet 116. In an embodiment, to make the fixed magnet 116 more resistant to accidental flipping the fixed magnet 116 has a higher magnetic anisotropy than the free magnet structure 106. In another embodiment, a synthetic antiferromagnetic (SAF) structure 118 can be disposed between the electrode 120 and the fixed magnet 116 in order to prevent accidental flipping of the magnetization 156 in the fixed magnet 116 as illustrated in FIG. 1A.

FIG. 1H illustrates cross-sectional view of the SAF structure 118 in an accordance of an embodiment of the present invention In an embodiment, the SAF structure 118 includes a non-magnetic layer 118B sandwiched between a first pinning ferromagnet 118A and a second pinning ferromagnet 118C as depicted in FIG. 1D. The first pinning ferromagnet 118A and the second pinning ferromagnet 118C are anti-ferromagnetically coupled to each other. In an embodiment, the first pinning ferromagnet 118A includes a layer of a magnetic metal such as Co, Ni, Fe, alloys such as CoFe, CoFeB, or alloys of magnetic metals such as Co, Ni, Fe or a bilayer of a magnetic/non-magnetic metals such but not limited to Co/Pd or a Co/Pt. In an embodiment, the non-magnetic layer 118B includes a ruthenium or an iridium layer. In an embodiment, the pinning ferromagnet 118C includes a layer of a magnetic metal comprising Fe, Co or Ni. Exemplary alloys include CoFe or CoFeB. Other magnetic alloys of one or more of Co, Ni, Fe are also possible, as is a bilayer structure including a magnetic/non-magnetic metals such but not limited to Co/Pd or a Co/Pt. In an embodiment, a ruthenium based non-magnetic layer 118B has a thickness between 0.3 nm and 1.0 nm to ensure that the coupling between the pinning ferromagnet 118A and the pinning ferromagnet 118C is anti-ferromagnetic in nature.

It is to be appreciated that an additional layer of non-magnetic spacer layer may exist between the fixed magnet 116 and the A structure 118 (not illustrated in FIG. 1A). A non-magnetic spacer layer enables coupling between the SAF structure 118 and the fixed magnet 116. In an embodiment, a non-magnetic spacer layer may include a metal such as Ta, Ru or Ir.

Referring again to FIG. 1A, the pMTJ device 104 further includes an electrode 120 on the SAF structure 118. In an embodiment, the electrode 120 includes a material such as Ta or TiN. In an embodiment, the electrode 120 has a thickness between 5 nm and 70 nm.

In an embodiment, the substrate 122 includes a suitable semiconductor material such as but not limited to, single crystal silicon, polycrystalline silicon and silicon on insulator (SOI). In another embodiment, substrate 122 includes other semiconductor materials such as germanium, silicon germanium or a suitable group III-N or a group III-V compound. Logic devices such as MOSFET transistors and access transistors and may be formed on the substrate 122. Logic devices such as access transistors may be integrated with memory devices such as SOT memory devices to form embedded memory. Embedded memory including SOT memory devices and logic MOSFET transistors can be combined to form functional integrated circuit such as a system on chip.

Referring once again to the plan view illustration of FIG. 1B, in an embodiment, the electrode 101 has a rectangular plan view profile and the pMTJ device 104 has a circular plan view profile as illustrated in FIG. 1B. In another embodiment, the pMTJ device 104 has a plan view profile that is rectangular. In another embodiment, when an MTJ memory device is an in-plane MTJ device, the in-plane MTJ device has a plan view profile that is elliptical. In an embodiment, the electrode 101 has a length, L_{SOT}, between 100 nm and 500 nm. In an embodiment, the electrode 101 has a thickness between 2 nm and 10 nm. In an embodiment, the electrode 101 has a width, W_{SOT}, between 10 nm and 50 nm. In an embodiment, the pMTJ device 104 has a broadest cross-sectional width, W_{MTJ}, that is similar or substantially similar to the width, W_{SOT}. In an embodiment, the pMTJ device 104 has a broadest cross-sectional width, W_{MTJ}, that is between 10 nm and 50 nm.

In an embodiment, the pMTJ device 104 has a center, C_{AM} and the electrode 101 has a center, C_{SOT}. In an embodiment, C_{MTJ} is aligned to C_{SOT} in X and Y directions, as illustrated in FIG. 1B. In another embodiment, C_{MTJ} is misaligned from the C_{SOT} in the Y-direction. Misalignment may range between 10 nm and 30 nm. The electrical resistivity of the electrode 101 may play a role in positioning of the pMTJ device 104 on the electrode 101 along the Y-direction in FIG. 1B.

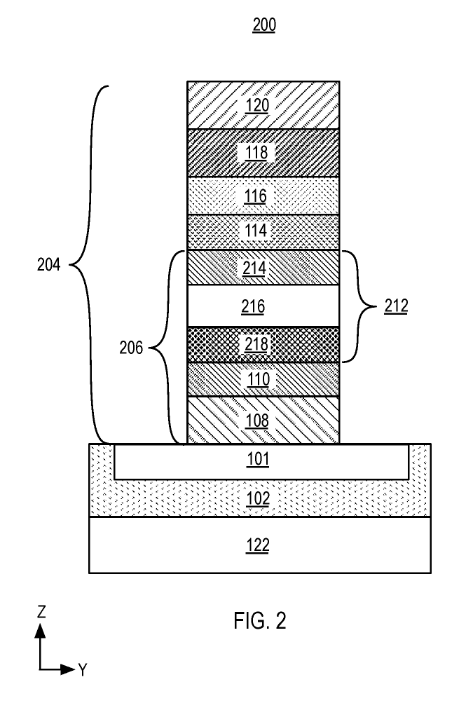

FIG. 2 illustrates a cross-sectional view of a pSOT memory device 200, including a pMTJ device 204. In the illustrative embodiment, the pMTJ device 204 includes a free magnet structure 206 that includes a composite free magnet 212 on the spacer 110. The composite free magnet 212 may include a free layer 214, a free layer 218 and conductive layer 216 between the free layer 214 and the free layer 218, as illustrated. A composite free magnet 212 may improve the thermal stability of the pSOT memory device 200. In the illustrative embodiment, the free layer 214 and the free layer 218 are ferromagnetically coupled. In the illustrative embodiment, the magnetic stability enhancement layer 108 has a magnetic anisotropy that is greater than a magnetic anisotropy of the composite free magnet 212.

The magnetic stability enhancement layer 108 provides stability and the spacer 110 couples the magnetic stability enhancement layer 108 to composite free magnet 212 via dipole coupling. The dipole coupling is proportional to the saturation magnetization and the thickness of the magnetic stability enhancement layer 108 and the composite free magnet 212. In an embodiment, the free layer 214 includes a magnetic material such as Co, Ni, Fe or alloys of these materials. In an embodiment, the free layer 214 includes a magnetic material such as CoB, FeB, CoFe or CoFeB. In some embodiments, the free layer 214 includes a Co_{100-x-y}FeₓB_{y}, where X and Y each represent atomic percent, further where X is between 50 and 80 and Y is between 10 and 40, and further where the sum of X and Y is less than 100. In one specific embodiment, X is 60 and Y is 20. In an embodiment, the free layer 218 includes a magnetic material such as Co, Ni, Fe or alloys of these materials. In an embodiment, the free layer 218 includes a magnetic material such as CoB, FeB, CoFe or CoFeB. In some embodiments, the free layer 218 includes a Co_{100-x-y}FeₓB_{y}, where X and Y each represent atomic percent, further where X is between 50 and 80 and Y is between 10 and 40, and further where the sum of X and Y is less than 100. In one specific embodiment, X is 60 and Y is 20. In some embodiments, the free layer 214 includes a material that is the same or substantially the same as the material of the free magnet 112. In some embodiments, the free layer 218 includes a material that is the same or substantially the same as the material of the free magnet 112.

The conductive layer 216 may include a metal such as tungsten, molybdenum or tantalum. Depending on embodiments, the conductive layer 216 has a thickness between 0.2 nm and 0.5 nm. In some embodiments, a conductive layer 216 having a thickness between 0.2 nm and 0.5 nm may be discontinuous. In some such embodiments portions of the free layer 214 may be in direct contact with the free layer 218.

In one exemplary embodiment, when a pSOT memory device 200 includes a composite free magnet 212, the spacer 110 comprises a material including oxygen and magnesium. A spacer 110 including oxygen and magnesium may enable a higher TMR in the pSOT memory device 200.

In other embodiments, the magnetic stability enhancement layer 108 may include one or more structures having one or more properties of the magnetic stability enhancement layer 108 described above in association with FIGS. 1C-1E.

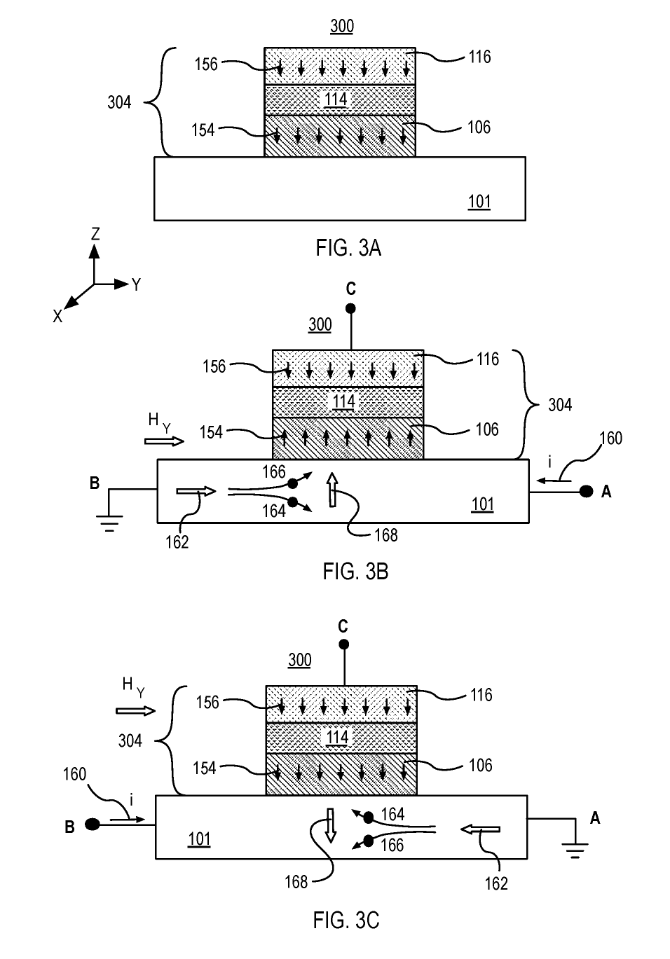

FIGS. 3A-3C illustrate a mechanism for switching a spin orbit torque (SOT) memory device such as a spin orbit torque (SOT) memory device 300 including a pMTJ device 304 on the electrode 101 including a spin orbit torque material. In the illustrative embodiment, the pMTJ device 304 includes one or more features of the pMTJ device 104, such as the free magnet structure 106, the fixed magnet 116 and the tunnel barrier 114 between the free magnet structure 106, the fixed magnet 116.

FIG. 3A illustrates a pSOT memory device 300 including the pMTJ device 304 on the electrode 101, where a magnetization 154 of the free magnet structure 106 is aligned in a direction parallel to the magnetization 156 of the fixed magnet 116. In an embodiment, the direction of magnetization 154 of the free magnet structure 106 and the direction of magnetization 156 of the fixed magnet 116 are both in the negative Z-direction as illustrated in FIG. 3A. As discussed above, when the magnetization 154 of the free magnet structure 106 is in the same direction as a magnetization 156 of the fixed magnet 116, pMTJ device 104 is in a low resistance state.

FIG. 3B illustrates the pMTJ device 304 of the spin orbit torque (SOT) memory device 300 switched to a high resistance state. In an embodiment, a reversal in the direction of magnetization 154 of the free magnet structure 106 in FIG. 3B relative to the direction of magnetization 154 of the free magnet structure 106 in FIG. 3A is brought about by (a) inducing a spin diffusion current 168 in the electrode 101 in the Y-direction, (by applying a positive voltage bias on terminal A with respect to a grounded terminal B), and (b) by applying an external magnetic field, H_{y}, 170 in the Y-direction.

In an embodiment, a charge current 160 is passed through the electrode 101 in the negative y-direction. In response to the charge current 160, an electron current 162 flows in the positive y-direction. The electron current 162 includes electrons with two opposing spin orientations, a type I electron 166, having a spin oriented in the negative x-direction and a type II electron 164 having a spin oriented in the positive X-direction. In an embodiment, electrons in the electron current 162 experience a spin dependent scattering phenomenon in the electrode 101. The spin dependent scattering phenomenon is brought about by a spin-orbit interaction between the nucleus of the atoms in the electrode 101 and the electrons in the electron current 162. The spin dependent scattering phenomenon causes type I electrons 166, whose spins are oriented in the negative x-direction (into the page of FIG. 3B), to be deflected upwards towards an uppermost portion of the electrode 101 and type II electrons 164 whose spins are oriented in the positive X-direction to be deflected downwards towards a lowermost portion of the electrode 101. The separation between the type I electrons 166 and the type II electrons 164 induces a polarized spin diffusion current 168 in the electrode 101. In an embodiment, the polarized spin diffusion current 168 is directed upwards toward the free magnet structure 106 of the pMTJ device 104, as is depicted in FIG. 3B. The polarized spin diffusion current 168 induces a Spin Hall torque on the magnetization 154 of the free magnet structure 106. In an embodiment, a torque can also be exerted on the magnetization 154 of the free magnet structure 106 by applying an external magnetic field, H_{Y}, in the Y-direction, as illustrated in FIG. 3B. In the illustrative embodiment, the external magnetic field, H_{Y}, provides a torque component (in the positive Z direction) to switch the magnetization 154 of the free magnet structure 106.

In an exemplary embodiment, the free magnet structure 106 includes the magnetic stability enhancement layer 108 and the free magnet 112 separated by spacer 110. In such an embodiment, the magnetic stability enhancement layer 108 experiences Spin Hall torque and undergoes magnetization switching. The free magnet 112 which is dipole coupled with the magnetic stability enhancement layer 108 and has a magnetic anisotropy that is weaker than a magnetic anisotropy of the magnetic stability enhancement layer 108, subsequently undergoes magnetization switching.

FIG. 3C illustrates the pMTJ device 304 of the spin orbit torque (SOT) memory device 300 switched to a low resistance state. In an embodiment, a reversal in the direction of magnetization 154 of the free magnet structure 106 in FIG. 3C compared to the direction of magnetization 154 of the free magnet structure 106 in FIG. 3B is brought about by (a) reversal in the direction of the spin diffusion current 168 in the electrode 101 (by applying a positive voltage bias on terminal B with respect to a grounded terminal A), and/ or (b) by applying an external magnetic field, H_{y}.

A read operation to determine a state of the MTJ device 104 may be performed by voltage biasing a third terminal C, connected to the fixed magnet 116 with respect to the either terminal and A and B, where the terminals A or B are grounded (not illustrated).

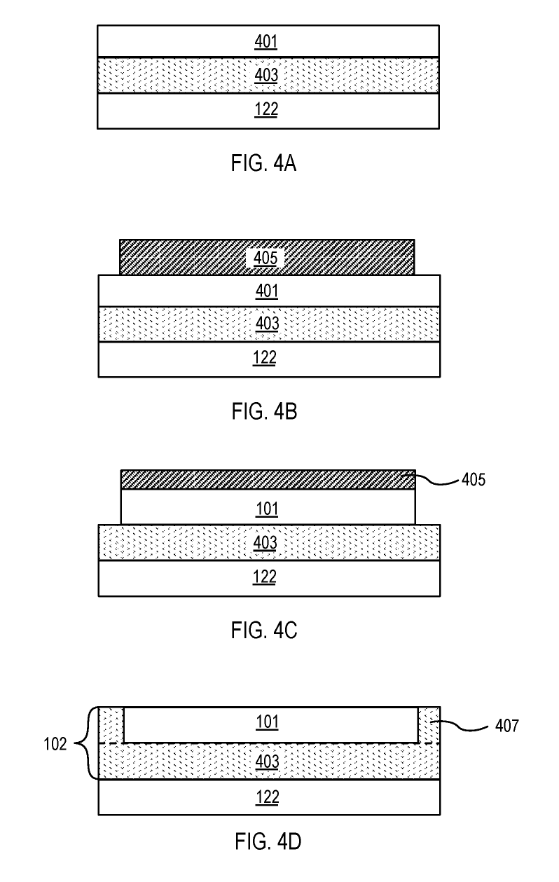

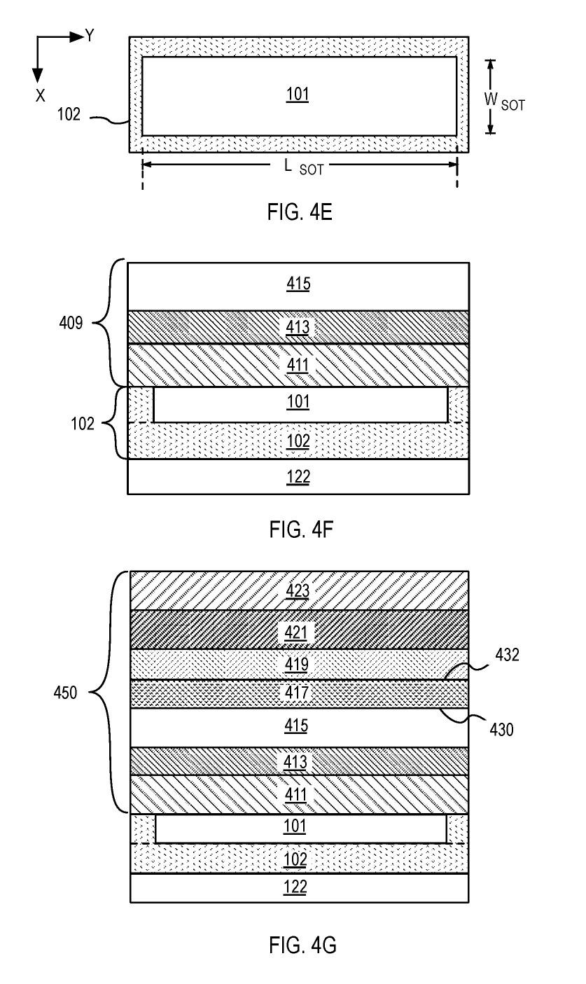

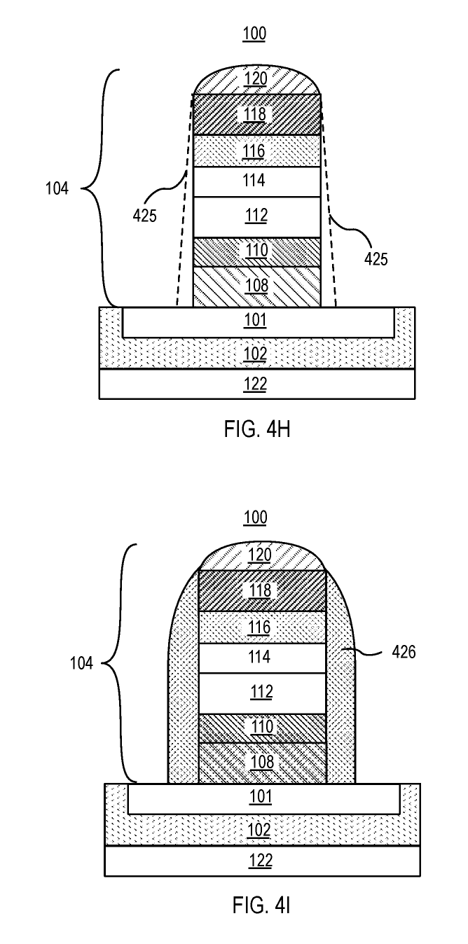

FIGS. 4A-4H illustrate cross-sectional views representing various operations in a method of fabricating pSOT memory device, such as the pSOT memory device 100 in accordance with embodiments of the present disclosure.

FIG. 4A illustrates a cross-sectional view of the formation of an electrode layer 401 on a dielectric layer 102 formed above a substrate 122. In an embodiment, the electrode layer 401 includes a material that is the same or substantially the same as the material of electrode 101. In an embodiment, the electrode layer 401 includes a metal such as platinum, beta-tungsten and beta-tantalum, or iridium manganese. In an embodiment, the electrode layer 401 is deposited using a physical vapor deposition process or a plasma enhanced chemical vapor deposition (PECVD) process. In some embodiments, the electrode layer 401 has a thickness that is between 4 nm and 15 nm.

In an embodiment, the dielectric layer 403 includes an electrically insulating material such as, but not limited to, silicon dioxide, silicon nitride, silicon carbide, or carbon doped silicon oxide. FIG. 4B illustrates a cross-sectional view of the structure in FIG. 4A following the formation of a mask 405 on the electrode layer 401. In some embodiments, the mask 405 is formed by a lithographic process. In other embodiments, the mask 405 includes a dielectric material that has been patterned. The mask 405 defines a size of an electrode that will subsequently be formed. In some embodiments, the mask 405 has a rectangular shape as is depicted in the plan view illustration of FIG. 1B. In other embodiments, the mask 405 has a circular, elliptical or a square shape.

FIG. 4C illustrates a cross-sectional view of the structure in FIG. 4B following the patterning of the electrode layer 401 to form an electrode 101. In an embodiment, the electrode layer 401 is patterned by a plasma etch process selectively to the mask 405. In some embodiments, upon completion of the etch process, any mask remaining after the etch process is subsequently removed.

FIG. 4D illustrates a cross-sectional view of the structure in FIG. 4C following the deposition of a dielectric layer 407 and a planarization process. In an embodiment, the dielectric layer 407 is deposited on the electrode 101 and on the dielectric layer 403. In some examples, the dielectric layer 407 may include a material that is substantially the same as the material of the dielectric layer 403. A planarization process is carried out to remove the dielectric layer 407 above the electrode 101. The portions of the of dielectric layer 407 remaining after the planarization process and the dielectric layer 403 are herein referred to as dielectric layer 102 housing the electrode 101. In an embodiment, the planarization process further removes an upper portion of the electrode 101. In an embodiment, the electrode 101 and the dielectric layer 407 surrounding the electrode 101 have uppermost surfaces that are substantially co-planar following the planarization process. In an embodiment, the planarization process is a chemical mechanical polish process. In an example, the planarization process forms an electrode 101 having a topographically smooth uppermost surface with a surface roughness that is less than 1 nm. In an embodiment, the electrode 101 has a resultant thickness between 2m and 10 nm after the planarization process.

FIG. 4E illustrates a plan view of the structure in FIG. 4D. In the illustrative embodiment, the electrode 101 is rectangular. A rectangular electrode 101, as depicted, has a length L_{SOT} and a width W_{SOT}. In some embodiments, the electrode 101 has a length, L_{SOT}, that is between 50 nm to 500 nm. In some embodiments, the electrode 101 has a width, W_{SOT}, between 20 nm to 40 nm.

FIG. 4F illustrates a cross-sectional view of the structure in 4D following the formation of a magnetic stability enhancement layer 411, a spacer layer 413 and a free magnetic layer 415 to form a composite free magnet 409 on the electrode 101 and on the dielectric layer 102. In some embodiments, the formation of the composite free magnet 409 includes depositing a magnetic stability enhancement layer 411 on the electrode 101 and on the dielectric layer 102, followed by depositing a spacer layer 413 on the magnetic stability enhancement layer 411 and followed by depositing a free magnetic layer 415 on the spacer layer 413.

In some embodiments, the deposition process is carried without an air break and the individual layers are blanket deposited using a variety of deposition processes in a cluster tool. Some layers may be deposited using a physical vapor deposition (PVD) process, for example. Other examples of deposition processes may include a co-sputter or a reactive sputtering process to deposit various layers of the composite free magnet 409.

In an embodiment, the magnetic stability enhancement layer 411 is deposited by a physical vapor deposition (PVD) process. In an embodiment, the magnetic stability enhancement layer 411 includes an alloy of a magnetic material and a non-magnetic material. In some embodiments, the non-magnetic material includes a metal such as platinum, palladium and iridium and the magnetic material includes a metal such as cobalt or iron. In an embodiment, the magnetic stability enhancement layer 411is a ferrimagnet alloy including manganese and an element such as germanium, aluminum or gallium. In some embodiments, the magnetic stability enhancement layer 411 includes a material that is the same or substantially the same as the material of the magnetic stability enhancement layer 108. In other embodiments, the magnetic stability enhancement layer 411 includes a multilayer stack of alternating layers of magnetic layer and a non-magnetic layer on the magnetic layer. In some such embodiments, the non-magnetic layer and the magnetic layer each include materials that are respectively the same or substantially the same as the material of the non-magnetic layer 108B and the material of the magnetic layer 108A. In one embodiment, the non-magnetic layer 108B may include a metal such as platinum, palladium or iridium and magnetic layer 108A may include a magnetic material such as cobalt.

The spacer layer 413 is deposited on the magnetic stability enhancement layer 411 to enable ferromagnetic coupling between the magnetic stability enhancement layer 411 and a subsequent free magnet that will be formed. In an embodiment, the spacer layer 413 is deposited using a PVD process. In an embodiment, the spacer layer 413 includes a material that is the same or substantially the same as the material of the spacer 110. In various embodiments, the spacer layer 413 is deposited to a thickness that depends on the choice of material utilized. The thickness of the spacer layer 413 advantageously provides ferromagnetic coupling between the magnetic stability enhancement layer 411 and the free magnetic layer 415 and ranges between 3 nm and 5 nm.

Referring again to FIG. 4F, the free magnetic layer 415 is deposited on the spacer layer 413. In an embodiment, the free magnetic layer 415 is deposited using a PVD process. In an embodiment, the free magnetic layer 415 includes a material that is the same or substantially the same as the material of the free magnet 112. In an embodiment, the deposition process forms a free magnetic layer 415 including CoFeB that is amorphous. In an embodiment, the free magnetic layer 415 is deposited to a thickness between 0.9 nm-2.0 nm to fabricate a perpendicular MTJ device.

In another embodiment, forming the composite free magnet 409 includes depositing a first free magnet on the spacer layer 413, wherein the spacer layer 413 includes magnesium and oxygen, depositing a conductive layer on the first free magnet and depositing a second free magnet on the conductive layer. In some embodiments, the first magnetic layer includes a material that is substantially the same as the material of the free layer 218 and the second magnetic layer includes a material that is substantially the same as the material of the free layer 214 described in association with FIG. 2 above. In some such embodiments, the conductive layer includes a material that is substantially the same as the material of the conductive layer 216 described in association with FIG. 2 above.

FIG. 4G illustrates a cross-sectional view of the structure in FIG. 4E following the formation of a tunnel barrier layer 417 on the free magnetic layer 415, a fixed magnetic layer 419 on the tunnel barrier layer 417, SAF layer 421 on the fixed magnetic layer 419 and an electrode layer 423 on the SAF layer 421 to complete formation of a material layer stack 450 for a pMTJ device.

In some embodiments, a tunnel barrier layer 417 is blanket deposited on the free magnetic layer 415. In an embodiment, the tunnel barrier layer 417 includes a material such as MgO or Al₂O₃. In an exemplary embodiment, the tunnel barrier layer 417 is an MgO and is deposited using a reactive sputter process. In an embodiment, the reactive sputter process is carried out at room temperature. In an embodiment, the tunnel barrier layer 417 is deposited to a thickness between 0.8 nm to 1 nm. In an embodiment, the deposition process is carried out in a manner that yields a tunnel barrier layer 417 having an amorphous structure. In some examples, the amorphous tunnel barrier layer 417 becomes crystalline after a high temperature anneal process to be described further below. In other embodiments, the tunnel barrier layer 417 is crystalline as deposited.

In an embodiment, the fixed magnetic layer 419 is blanket deposited on an uppermost surface of the tunnel barrier layer 417. In an embodiment, the deposition process includes a physical vapor deposition (PVD) or a plasma enhanced chemical vapor deposition process. In an embodiment, the PVD deposition process includes an RF or a DC sputtering process. In an exemplary embodiment, the fixed magnetic layer 419 is Co_{100 -x-y}FeₓB_{y}, where X and Y each represent atomic percent, further where X is between 50 and 80 and Y is between 10 and 40, and further where the sum of X and Y is less than 100. In some embodiments, the fixed magnetic layer 419 includes a material that is the same or substantially the same as the material of the fixed magnet 116 described above. In some examples, the fixed magnetic layer 419 may be deposited to a thickness between 2.0 nm and 3.0 nm.

The process is continued with deposition of layers utilized to form a SAF layer 421. In some embodiments, the layers utilized to form SAF layer 421 are blanket deposited on the fixed magnetic layer 421 using a PVD process. The layers utilized to form SAF layer 421 are the same or substantially the same as the layers in the SAF structure 118 described above.

In an embodiment, the deposition process concludes with a blanket deposition of an electrode layer 421 on an uppermost surface of the SAF layer 421. In an embodiment, the electrode layer 423 includes a material that is suitable to act as a hardmask during a subsequent etching of the pMTJ material layer stack 450 to form a pMTJ device on the electrode 101. In an embodiment, the electrode layer 423 includes a material such as TiN, Ta or TaN. In an embodiment, the thickness of the top electrode layer ranges from 5 nm to 70 nm. The thickness of the electrode layer 423 is chosen to accommodate patterning of the pMTJ material layer stack 450 to form a pMTJ device.

In an embodiment, after all the layers in the pMTJ material layer stack 450 are deposited, an anneal is performed. In an embodiment, the anneal process enables formation of a crystalline MgO—tunnel barrier layer 417 to be formed. In an embodiment, the anneal is performed immediately post deposition but before patterning of the pMTJ material layer stack 450. A post-deposition anneal of the pMTJ material layer stack 450 is carried out in a furnace at a temperature between 300 to 350 degrees Celsius in a forming gas environment. In an embodiment, the forming gas includes a mixture of H₂ and N₂ gas. In an embodiment, the annealing process promotes solid phase epitaxy of the free magnetic layer 415 to follow a crystalline template of the tunnel barrier layer 417 (e.g., MgO) that is directly above the free magnetic layer 415. In an embodiment, the anneal also promotes solid phase epitaxy of the fixed magnetic layer 419 to follow a crystalline template of the tunnel barrier layer 417 (e.g., MgO) that is directly below the fixed magnetic layer 419. <001>Lattice matching between the tunnel barrier layer 417 and the free magnetic layer 415 and <001>lattice matching between the tunnel barrier layer 417 and the fixed magnetic layer 419 enables a TMR ratio between 90% and 110% to be obtained in the pMTJ material layer stack 450.

In an embodiment, when the free magnetic layer 415 includes boron, the annealing process enables boron to diffuse away from an interface 430 between the free magnetic layer 415 and the tunnel barrier layer 417. The process of diffusing boron away from the interface 430 enables lattice matching between the free magnetic layer 415 and the tunnel barrier layer 417. In an embodiment, when the fixed magnetic layer 419 includes boron, the annealing process enables boron to diffuse away from an interface 432 between the fixed magnetic layer 419 and the tunnel barrier layer 417.

In an embodiment, the annealing process is also performed in the presence of a magnetic field which sets a direction of magnetization of the fixed magnetic layer 419, the free magnetic layer 415 and the magnetic stability enhancement layer 411. In an embodiment, during the annealing process, an applied magnetic field that is directed perpendicular to a plane of pMTJ material layer stack 450 enables a perpendicular anisotropy to be set in the fixed magnetic layer 419, in the free magnetic layer 415 and in the magnetic stability enhancement layer 411. In an embodiment, the annealing process initially aligns the magnetization of the fixed magnetic layer 419, magnetization of the free magnetic layer 415 and the magnetization of the magnetic stability enhancement layer 411 to be parallel to each other and perpendicular to the plane of the pMTJ material layer stack 450.

While one pMTJ material layer stack 450 has been described in this embodiment, a material layer stack for forming the pMTJ device 204 illustrated in FIG. 2 can also be fabricated by the deposition techniques described above.

FIG. 4H illustrates a cross-sectional view of the structure in FIG. 4G following patterning and etching of the pMTJ material layer stack 450. In an embodiment, the patterning process includes forming a mask (not shown) over the material layer stack 450. The mask defines a shape and size of a pMTJ device and a location where the pMTJ device is to be subsequently formed with respect the electrode 101. In an embodiment, the patterning process includes etching the electrode layer 423 by a plasma etch process to form an electrode 120. In an embodiment, plasma etch process possesses sufficient ion energy and chemical reactivity to render vertical etched sidewalls of the electrode 120.

In an embodiment, the plasma etch process is then continued to pattern the remaining layers of the pMTJ material layer stack 450 to form a pMTJ device 104. The plasma etch process etches the various layers in the pMTJ material layer stack 450 to form a SAF structure 118, a fixed magnet 116, a tunnel barrier 114, a free magnet 112, a spacer layer 110, and a magnetic stability enhancement layer 108. The plasma etch process also exposes the electrode 101 and portions of the underlying dielectric layer 102. In some embodiments, depending on the etch parameters, the pMTJ device 104 may have sidewalls that are tapered as indicated by the dashed lines 425. The pMTJ device 104 formed over the electrode 101, constitutes a perpendicular spin orbit torque memory device 100.

FIG. 4I illustrates a cross-sectional view of the structure in FIG. 4G following the formation of a dielectric spacer 426 adjacent to the pMTJ device 104. In an embodiment, a dielectric spacer layer is deposited on the pMTJ device 104 and on the uppermost surface of the electrode 101 and on the dielectric layer 102. In an embodiment, the dielectric spacer layer is deposited without a vacuum break following the plasma etch process. In an embodiment, the dielectric spacer layer includes a material such as, but not limited to, silicon nitride, carbon doped silicon nitride or silicon carbide. In an embodiment, the dielectric spacer layer includes an insulator layer that does not have an oxygen content to minimize potential oxidation of magnetic layers. In an embodiment, the dielectric spacer layer is etched by a plasma etch process forming dielectric spacer 426 on sidewalls of the pMTJ device 104. In some examples, the etch process may cause an uppermost portion of the dielectric layer 102 to become partially recessed leading to partial exposure of sidewalls of the electrode 101.

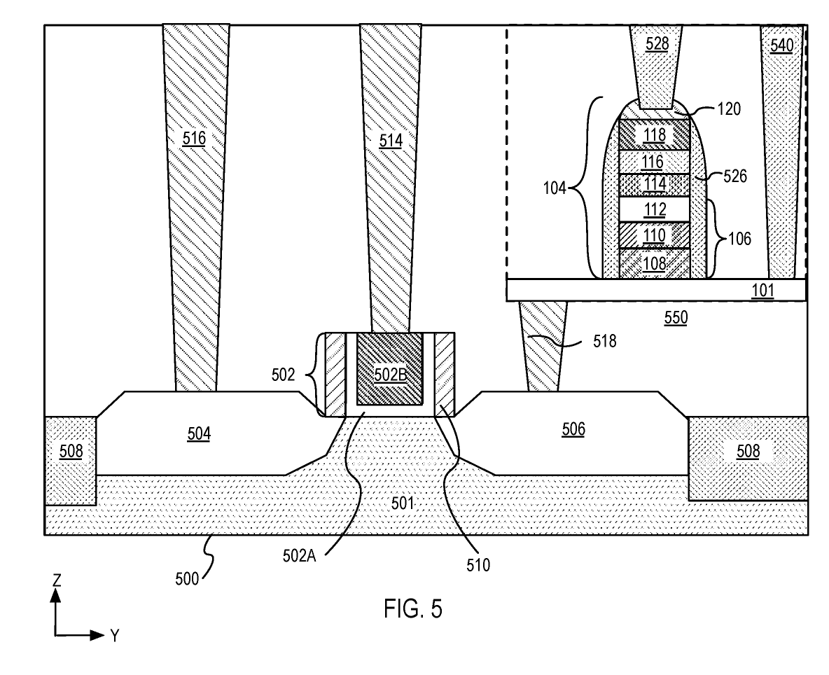

FIG. 5 illustrates a SOT device coupled to an access transistor 500. In an embodiment, the SOT memory device 100 includes a MTJ device 104 on a SOT electrode 101, described in association with FIG. 1A. The SOT memory device 100 may include one or more features of the SOT memory device 100 described above in association with FIGS. 1A. In an embodiment, the perpendicular spin orbit torque memory device 100 includes a pMTJ device such as an pMTJ device 104, on an electrode 101, described in association with FIG. 1A.

In an embodiment, the transistor 500 has a source region 504, a drain region 506 and a gate 502. The transistor 500 further includes a gate contact 514 above and electrically coupled to the gate 502, a source contact 516 above and electrically coupled to the source region 504, and a drain contact 518 above and electrically coupled to the drain region 506 as is illustrated in FIG. 5. In the illustrative embodiment, the pMTJ device 104 includes a free magnet structure 106. The free magnet structure 106 includes a magnetic stability enhancement layer 108 on the electrode 101, a spacer 110 on the magnetic stability enhancement layer 108 and a free magnet 112 on the spacer 110. In the illustrative embodiment, the magnetic stability enhancement layer 108 has a magnetic anisotropy that is greater than a magnetic anisotropy of the free magnet 112. The magnetic stability enhancement layer 108 advantageously improves thermal stability of the MTJ device 104 and the spacer 110 couples the magnetic stability enhancement layer 108 to free magnet 112 via dipole coupling. The dipole coupling is proportional to the saturation magnetization and thickness of the magnetic stability enhancement layer 108 and free magnet 112. The pMTJ device 104 further includes a tunnel barrier 114 having a material such as an MgO or Al₂O₃, on the free magnet 112 and a fixed magnet 116 on the tunnel barrier 114.

In an illustrative embodiment, one portion of electrode 101 is in electrical contact with the drain contact 518 of transistor 500. A pMTJ contact 528 is on and electrically coupled with the electrode 120 of the pMTJ device 104. An interconnect metallization structure 540 is on and electrically coupled with the electrode 101, and the pMTJ device 104 is between the drain contact 538 and the interconnect metallization structure 540. In the illustrative embodiment, the pMTJ device 104 is laterally between the drain contact 538 and interconnect metallization structure 540. In some embodiments, the pMTJ device 104 is laterally closer to the drain contact 538 than to interconnect metallization structure 540. In other embodiments, the pMTJ device 104 is laterally closer to the interconnect metallization structure 540 than to the drain contact 538. In some embodiments, the pMTJ device 104 is approximately mid-way, laterally, between the interconnect metallization structure 540 and the drain contact 538. In an embodiment, the electrode 101 is also above and adjacent to a dielectric layer 550. In an embodiment, the dielectric layer 550 includes an electrically insulating material such as, but not limited to, silicon dioxide, silicon nitride, silicon carbide, or carbon doped silicon oxide.

In an embodiment, the underlying substrate 501 represents a surface used to manufacture integrated circuits. Suitable substrate 501 includes a material such as single crystal silicon, polycrystalline silicon and silicon on insulator (SOI), as well as substrates formed of other semiconductor materials. The substrate 501 may also include semiconductor materials, metals, dielectrics, dopants, and other materials commonly found in semiconductor substrates.

In an embodiment, the access transistor 500 associated with substrate 501 are metal-oxide-semiconductor field-effect transistors (MOSFET or simply MOS transistors), fabricated on the substrate 501. In various implementations of the invention, the access transistor 500 may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors.

In an embodiment, the access transistor 500 of substrate 501 includes a gate 502 including at least two layers, a gate dielectric layer 502A and a gate electrode 502B. The gate dielectric layer 502A may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer 502A to improve its quality when a high-k material is used.

The gate electrode 502B of the access transistor 500 of substrate 501 is formed on the gate dielectric layer 502A and may consist of at least one P-type workfunction metal or N-type workfunction metal, depending on whether the transistor is to be a PMOS or an NMOS transistor. In some implementations, the gate electrode 502B may consist of a stack of two or more metal layers, where one or more metal layers are workfunction metal layers and at least one metal layer is a conductive fill layer.

For a PMOS transistor, metals that may be used for the gate electrode 502B include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode 502B may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode 502B may consist of one or more U-shaped metal layers formed atop one or more planar, non-U-shaped layers.

In some implementations of the invention, a pair of sidewall spacers 51A may be formed on opposing sides of the gate stack that bracket the gate stack. The sidewall spacers 51A may be formed from a material such as silicon nitride, silicon oxide, silicon carbide, silicon nitride doped with carbon, and silicon oxynitride. Processes for forming sidewall spacers may include deposition and etching process operations. In an alternate implementation, a plurality of spacer pairs may be used, for instance, two pairs, three pairs, or four pairs of sidewall spacers may be formed on opposing sides of the gate stack. Source region 504 and drain region 506 may be formed within the substrate adjacent to the gate stack of each MOS transistor. The source region 504 and drain region 506 are generally formed using either an implantation/diffusion process or an etching/deposition process. In the former process, dopants such as boron, aluminum, antimony, phosphorous, or arsenic may be ion-implanted into the substrate to form the source region 504 and drain region 506. An annealing process that activates the dopants and causes them to diffuse further into the substrate typically follows the ion implantation process. In the latter process, the substrate 501 may first be etched to form recesses at the locations of the source and drain regions. An epitaxial deposition process may then be carried out to fill the recesses with material that is used to fabricate the source region 504 and drain region 506. In some implementations, the source region 504 and drain region 506 may be fabricated using a silicon alloy such as silicon germanium or silicon carbide. In some implementations, the epitaxially deposited silicon alloy may be doped in situ with dopants such as boron, arsenic, or phosphorous. In further embodiments, the source region 504 and drain region 506 may be formed using one or more alternate semiconductor materials such as germanium or a group III-V material or alloy. And in further embodiments, one or more layers of metal and/or metal alloys may be used to form the source region 504 and drain region 506. In the illustrative embodiment, an isolation 508 is adjacent to the source region 504, drain region 506 and portions of the substrate 501.

In an embodiment, a source contact 516 and a drain contact 518 are formed in a dielectric layer 511 and in the dielectric layer 512 above the gate electrode 502B. In the illustrative embodiment, a source metallization structure 524 is coupled with the source contact 516 and a gate metallization structure 526 is coupled with the gate contact 514. In the illustrated embodiment, a dielectric layer is adjacent to the gate contact 514, drain contact 518, source contact 516.

In an embodiment, the source contact 516, the drain contact 518 and gate contact 518 each include a multi-layer stack. In an embodiment, the multi-layer stack includes two or more distinct layers of metal such as a layer of Ti, Ru or Al and a conductive cap on the layer of metal. The conductive cap may include a material such as W or Cu. In some embodiments, a dielectric spacer 526 may be adjacent to the MTJ device 104, where the dielectric layer includes a material that is the same or substantially the same as the material of the dielectric spacer 426.

The isolation 508, and dielectric layer 520 may include any material that has sufficient dielectric strength to provide electrical isolation such as, but not, limited silicon dioxide, silicon nitride, silicon oxynitride, carbon doped nitride and carbon doped oxide.

In an embodiment, when the transistor 500 is energized in a manner that causes charge current to flow through the electrode 101, a Spin Hall current is generated in the electrode 101. In one such embodiment, the interconnect metallization structure 540 is voltage biased with respect to the source contact 516 (with a bias applied to gate contact 514 to enable a channel under the gate 502 to enable charge current to flow through the SOT electrode 101. The Spin Hall current will exert a torque on the magnetization of the magnetic stability enhancement layer 108 of the pMTJ device 104, enabling a change in a direction of magnetization in the magnetic stability enhancement layer 108. In the illustrative embodiment, the magnetization in the free magnet 112, which is dipole coupled with the magnetic stability enhancement layer 108 will change direction in response to a change in direction of magnetization in the magnetic stability enhancement layer 108. The mechanism for generation of Spin Hall current in a SOT electrode such as SOT electrode 101 is described above in association with FIGS. 3B-3C.

A read operation of the pMTJ device 104 may be enabled, for example, by applying a bias voltage between 0.1V and 0.2V between on the MTJ contact 528 and the interconnect metallization structure 540.

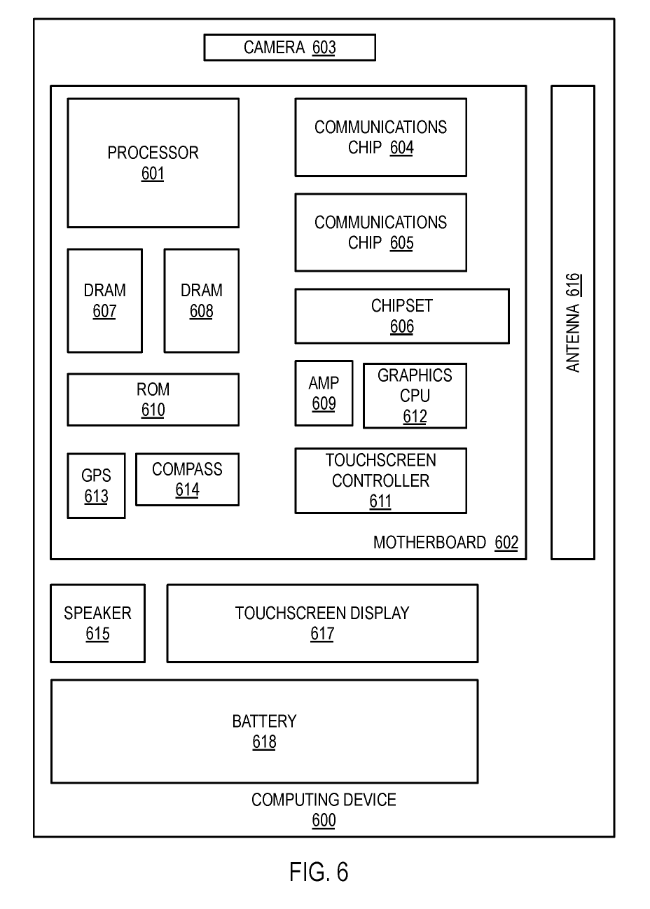

FIG. 6 illustrates a computing device 600 in accordance with embodiments of the present disclosure. As shown, computing device 600 houses a motherboard 602. Motherboard 602 may include a number of components, including but not limited to a processor 601 and at least one communication chip 605. Processor 601 is physically and electrically coupled to the motherboard 602. In some implementations, communication chip 605 is also physically and electrically coupled to motherboard 602. In further implementations, communication chip 605 is part of processor 601.

Depending on its applications, computing device 600 may include other components that may or may not be physically and electrically coupled to motherboard 602. These other components include, but are not limited to, volatile memory (e.g., DRAM), non-volatile memory (e.g., ROM), flash memory, a graphics processor, a digital signal processor, a crypto processor, a chipset 606, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communication chip 605 enables wireless communications for the transfer of data to and from computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 605 may implement any of a number of wireless standards or protocols, including but not limited to Wi-Fi (IEEE 802.6 family), WiMAX (IEEE 802.6 family), IEEE 802.10, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 600 may include a plurality of communication chips 604 and 605. For instance, a first communication chip 605 may be dedicated to shorter range wireless communications such as Wi-Fi and Bluetooth and a second communication chip 604 may be dedicated to longer range wireless communications such as GPS, EDGE, GPRS, CDMA, WiMAX, LTE, Ev-DO, and others.

Processor 601 of the computing device 600 includes an integrated circuit die packaged within processor 601. In some embodiments, the integrated circuit die of processor 601 includes one or more memory devices, such as a spin orbit torque memory device 100, including a pMTJ device 104, and spin orbit torque memory device 100, including a pMTJ device 204 in accordance with embodiments of the present disclosure. The term “processor” may refer to any device or portion of a device that processes electronic data from registers and/or memory to transform that electronic data into other electronic data that may be stored in registers and/or memory.

Communication chip 605 also includes an integrated circuit die packaged within communication chip 606. In another embodiment, the integrated circuit die of communication chips 604, 605 include a memory array with memory cells including at least one pSOT memory device such as a pSOT memory device 200 including a MTJ device 204 on a SOT electrode 101.

In various examples, one or more communication chips 604, 605 may also be physically and/or electrically coupled to the motherboard 602. In further implementations, communication chips 604 may be part of processor 601. Depending on its applications, computing device 600 may include other components that may or may not be physically and electrically coupled to motherboard 602. These other components may include, but are not limited to, volatile memory (e.g., DRAM) 607, 608, non-volatile memory (e.g., ROM) 610, a graphics CPU 612, flash memory, global positioning system (GPS) device 613, compass 614, a chipset 606, an antenna 616, a power amplifier 609, a touchscreen controller 66, a touchscreen display 617, a speaker 615, a camera 603, and a battery 618, as illustrated, and other components such as a digital signal processor, a crypto processor, an audio codec, a video codec, an accelerometer, a gyroscope, and a mass storage device (such as hard disk drive, solid state drive (SSD), compact disk (CD), digital versatile disk (DVD), and so forth), or the like. In further embodiments, any component housed within computing device 600 and discussed above may contain a stand-alone integrated circuit memory die that includes one or more arrays of memory cells including one or more memory devices, such as a spin orbit torque memory device 100, including a pMTJ device 104, and spin orbit torque memory device 100, including a pMTJ device 204 built in accordance with embodiments of the present disclosure.

In various implementations, the computing device 600 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

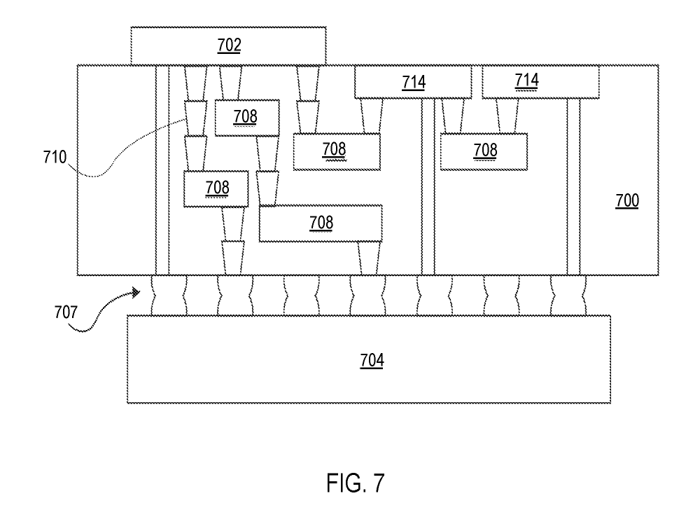

FIG. 7 illustrates an integrated circuit (IC) structure 700 that includes one or more embodiments of the disclosure. The integrated circuit (IC) structure 700 is an intervening substrate used to bridge a first substrate 702 to a second substrate 704. The first substrate 702 may be, for instance, an integrated circuit die. The second substrate 704 may be, for instance, a memory module, a computer mother, or another integrated circuit die. Generally, the purpose of an integrated circuit (IC) structure 700 is to spread a connection to a wider pitch or to reroute a connection to a different connection. For example, an integrated circuit (IC) structure 700 may couple an integrated circuit die to a ball grid array (BGA) 706 that can subsequently be coupled to the second substrate 704. In some embodiments, the first and second substrates 702/704 are attached to opposing sides of the integrated circuit (IC) structure 700. In other embodiments, the first and second substrates 702/704 are attached to the same side of the integrated circuit (IC) structure 700. And in further embodiments, three or more substrates are interconnected by way of the integrated circuit (IC) structure 700.

The integrated circuit (IC) structure 700 may be formed of an epoxy resin, a fiberglass-reinforced epoxy resin, a ceramic material, or a polymer material such as polyimide. In further implementations, the integrated circuit (IC) structure may be formed of alternate rigid or flexible materials that may include the same materials described above for use in a semiconductor substrate, such as silicon, germanium, and other group III-V and group IV materials. The integrated circuit (IC) structure may include metal interconnects 708 and vias 710, including but not limited to through-silicon vias (TSVs) 710. The integrated circuit (IC) structure 700 may further include embedded devices 714, including both passive and active devices. Such devices include, but are not limited to, capacitors, decoupling capacitors, resistors, inductors, fuses, diodes, transformers, device structure including transistors, such as transistors 500 and 520 coupled with a with one at least one pMTJ memory device such as a pMTJ device 104, or pMTJ device 204 where the pMTJ devices 104 includes a free magnet structure having a free magnet that is dipole coupled to a magnetic stability enhancement layer and where the pMTJ devices 204 includes a free magnet structure having a composite free magnet that is dipole coupled to a magnetic stability enhancement layer, (such as described above) for example. The integrated circuit (IC) structure 700 may further include embedded devices 714 such as one or more resistive random-access devices, sensors, and electrostatic discharge (ESD) devices. More complex devices such as radio-frequency (RF) devices, power amplifiers, power management devices, antennas, arrays, sensors, and MEMS devices may also be formed on the integrated circuit (IC) structure 700. In accordance with embodiments of the present disclosure, apparatuses or processes disclosed herein may be used in the fabrication of integrated circuit (IC) structure 700.

Accordingly, one or more embodiments of the present disclosure relate generally to the fabrication of embedded microelectronic memory. The microelectronic memory may be non-volatile, wherein the memory can retain stored information even when not powered. One or more embodiments of the present disclosure relate to the fabrication of a perpendicular spin orbit torque memory device such as the perpendicular spin orbit torque memory device 100 or a perpendicular spin orbit torque memory device 200. The perpendicular spin orbit torque memory devices 100, 200 may be used in an embedded non-volatile memory application

Thus, embodiments of the present disclosure include spin orbit torque memory devices with enhanced stability and methods to form the same.

Specific embodiments are described herein with respect to perpendicular spin orbit torque devices. It is to be appreciated that embodiments described herein may also be applicable to other non-volatile memory devices. Such non-volatile memory devices may include, but are not limited to, magnetic random access memory (MRAM) devices, spin torque transfer memory (STTM) devices such as in-plane STTM or perpendicular STTM devices.

What is claimed is:

1. A perpendicular spin orbit torque (pSOT) memory device, comprising:
a first electrode, comprising a spin orbit torque material;
a material layer stack adjacent to the first electrode, the material layer stack comprising:
a free magnet structure, wherein the free magnet structure comprises:
a magnetic stability enhancement layer comprising a ferromagnetic material;
a free magnet; and
a spacer between magnetic stability enhancement layer and the free magnet, wherein the free magnet is dipole coupled with the magnetic stability enhancement layer;
a fixed magnet;
a tunnel barrier between the free magnet structure and the fixed magnet; and
a second electrode coupled with the fixed magnet.

2. The pSOT memory device of claim 1, wherein the spin orbit torque material comprises tantalum, tungsten, or platinum.

3. The pSOT memory device of claim 1, wherein the coupling layer comprises copper, platinum, palladium, ruthenium, or titanium.

4. The pSOT memory device of claim 1, wherein the coupling layer comprises oxygen and an element such as magnesium, tungsten, tantalum, titanium, aluminum copper or silicon.

5. The pSOT memory device of claim 1, wherein the coupling layer has a thickness between 1 nm and 5 nm.

6. The pSOT memory device of claim 1, wherein the magnetic stability enhancement layer has a magnetic anisotropy that is greater than a magnetic anisotropy of the free magnet.

7. The pSOT memory device of claim 1, wherein the magnetic stability enhancement layer includes an alloy of a magnetic material and a non-magnetic material.

8. The pSOT memory device of claim 7, wherein the non-magnetic material comprises platinum, palladium and iridium and the magnetic material comprises cobalt or iron.

9. The pSOT memory device of claim 7, wherein the magnetic stability enhancement layer has thickness between 2 nm and 10 nm.

10. The pSOT memory device of claim 1, wherein the magnetic stability enhancement layer comprises manganese, and germanium, aluminum or gallium.

11. The pSOT memory device of claim 1, wherein the magnetic stability enhancement layer includes a multilayer stack of alternating layers of magnetic and non-magnetic materials, wherein the number of alternating layers ranges between 4 and 10.

12. The pSOT memory device of claim 11, wherein the non-magnetic layers comprises platinum, palladium and iridium, and wherein the magnetic material comprises cobalt.

13. The pSOT memory device of claim 1, wherein the free magnet further comprises:
a first free layer;
a conductive layer; and
a second free layer, and wherein the spacer comprises oxygen and magnesium.

14. The pSOT memory device of claim 13, wherein the first and the second free magnet comprise cobalt, boron and iron, and the conductive layer comprises tungsten, molybdenum, or tantalum.

15. The pSOT memory device of claim 14, wherein conductive layer has a thickness between 0.1 nm and 0.5 nm and is discontinuous.

16. A method of fabricating a perpendicular spin orbit torque (pSOT) device, the method comprising:
depositing first electrode, comprising a spin orbit torque material above a substrate;
patterning the first electrode to form a spin orbit torque electrode;
forming a material layer stack for a magnetic tunnel junction (MTJ) memory device on the spin orbit torque electrode, the forming comprising:
depositing a magnetic stability enhancement layer on the spin orbit torque electrode;
forming a spacer layer above the magnetic stability enhancement layer;
depositing a free magnetic layer on the spacer layer;
depositing a tunnel barrier layer on the free magnetic layer;
depositing a fixed magnetic layer on the tunnel barrier layer;
depositing a top electrode layer on the fixed magnetic layer;
etching the material layer stack to form a memory device over a portion of the spin orbit torque electrode, wherein the free magnetic layer is magnetically coupled with the magnetic stability enhancement layer.

17. The method of claim 16, wherein forming the spacer layer includes depositing a metallic coupling layer between the magnetic stability enhancement layer and the free magnetic layer.

18. The method of claim 16, wherein forming the spacer layer includes depositing a layer comprising oxygen and magnesium, tungsten, tantalum, titanium, aluminum, copper or silicon.

19. The method of claim 16, wherein the process further comprises performing a high temperature anneal to enable <001> lattice matching of the free magnetic layer to the tunnel barrier layer.

20. The method of claim 16, wherein forming the free magnetic layer comprises:
depositing a first free magnetic layer on the spacer layer, wherein the spacer layer includes magnesium and oxygen;
depositing a conductive layer on the first free magnetic layer; and
depositing a second free magnetic layer on the conductive layer.

21. An apparatus comprising:
a transistor above a substrate, the transistor comprising:
a drain contact coupled to a drain;
a source contact coupled to a source; and
a gate contact coupled to a gate;
a perpendicular spin orbit torque (pSOT) memory device coupled with the drain contact, the pSOT memory device comprising:
a first electrode, comprising a spin orbit torque material; and
a material layer stack adjacent to the first electrode, the material layer stack comprising:
a free magnet structure, wherein the free magnet structure comprises:
a magnetic stability enhancement layer, comprising a magnetic material;
a free magnet; and
a spacer between magnetic stability enhancement layer and the free magnet,
wherein the free magnet is coupled with the magnetic stability enhancement layer;
a fixed magnet;
a tunnel barrier between the free magnet structure and the fixed magnet; and
a second electrode on the fixed magnet; and
an interconnect metallization structure coupled with the first electrode, wherein the material layer stack is laterally between the drain contact and the interconnect metallization structure.

22. The pSOT memory device of claim 21, wherein the coupling layer comprises oxygen and an element such as magnesium, tungsten, tantalum, titanium, aluminum copper or silicon.

23. The apparatus of claim 21, wherein the magnetic stability enhancement layer has a magnetic anisotropy that is greater than a magnetic anisotropy of the free magnet.

24. The SOT device of claim 21, wherein the magnetic stability enhancement layer includes an alloy of a magnetic material and a non-magnetic material and wherein the non-magnetic material comprises platinum, palladium, or iridium and the magnetic material comprises cobalt or iron.
